(19) United States
(12) Patent Application Publication
(10) Pub. No.: US 2009/0072282 A1
(43) Pub. Date: Mar. 19, 2009

(54) Image Sensor and Method for Manufacturing the Same

(76) Inventor: Sun Chan LEE, Changnyeong-gun (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/210,159

(22) Filed: Sep. 12, 2008

(30) Foreign Application Priority Data
Sep. 14, 2007 (KR) 10-2007-0093573

(51) Int. Cl. H01L 31/00; H01L 21/00

(52) U.S. Cl. 257/292; 438/70; 257/E31.001; 257/E21.001

(57) ABSTRACT

Provided is an image sensor. In the image sensor, a transistor region is on a substrate, and a photo diode region is at one side of the transistor region. A dielectric layer is formed on the transistor region and the photo diode region. A metal line is formed on the dielectric layer in the transistor region. A color filter is formed on the dielectric layer in the photo diode region.

### CROSS-REFERENCE TO RELATED APPLICATIONS

The present application claims priority under 35 U.S.C. §119 of Korean Patent Application No. 10-2007-0093573, filed Sep. 14, 2007, which is hereby incorporated by reference in its entirety.

### BACKGROUND

Embodiments relate to an image sensor and a method for manufacturing the same.

In general, an image sensor is a semiconductor device that converts an optical image to electric signals. Image sensors are generally classified into charge coupled device (CCD) image sensors and complementary metal oxide silicon (CMOS) image sensors (a CMOS image sensor is also known as a CIS).

The CIS includes a photo diode and a MOS transistor in each unit pixel, and sequentially processes electrical signals from each unit pixel in switching mode to realize images. A CIS according to a related art includes a photo diode region that converts a light signal into an electrical signal, and a transistor region that processes the converted electrical signal.

Meanwhile, as the thickness of back-end-of-line (BEOL) layers in the CIS structure increases, the amount of light arriving at the photo diode region decreases. In this case, since the amount of electron hole pairs (EHP) generated in the photodiode is relatively small, the transistor (Tr) and/or signal processing characteristics of the CIS may be less than optimal.

### BRIEF SUMMARY

Embodiments of the invention provide an image sensor and a method for manufacturing the same that can improve the transistor and/or processing characteristics of the image sensor by increasing the amount of light arriving at a photo diode.

In one embodiment, an image sensor may comprise a transistor region on a substrate; a photo diode region at one side of the transistor region; a dielectric layer having a first portion on the transistor region and a second portion on the photo diode region; a metal line on the first portion of the dielectric layer; and a color filter on the second portion of dielectric layer.

In another embodiment, a method for manufacturing an image sensor may comprise forming a transistor region on a substrate; forming a photo diode region at one side of the transistor region; forming a dielectric layer on the photo diode region and the transistor region; forming a metal line on the dielectric layer over the transistor region; selectively removing the dielectric layer on the photo diode region; and forming a color filter on the dielectric layer over the photo diode.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of an exemplary image sensor according to an embodiment of the invention.

FIGS. 2 to 3 are cross-sectional views illustrating an exemplary method for manufacturing an image sensor according to embodiments of the invention.

### DETAILED DESCRIPTION OF THE EMBODIMENTS

An exemplary image sensor and an exemplary method for manufacturing the same according to various embodiments will be described in detail with reference to the accompanying drawings.

In the description of such embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

### Embodiment 1

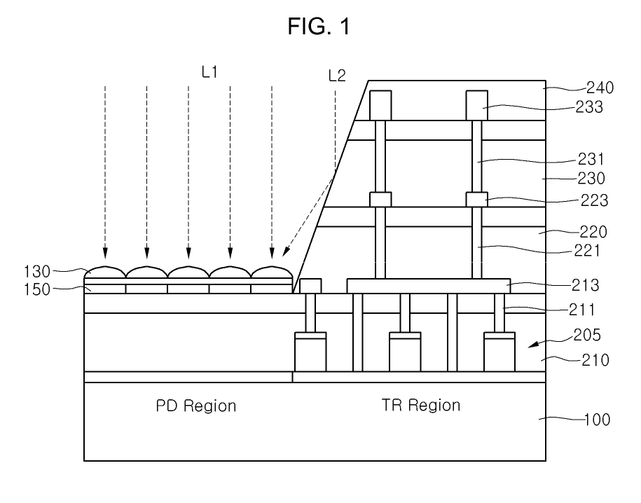

FIG. 1 is a cross-sectional view of an exemplary image sensor according to an embodiment of the invention.

The exemplary image sensor may include a transistor (TR) region; a photo diode (PD) region at one side of the transistor (TR) region; dielectric layers 210, 220, 230, 240 on the transistor (TR) region; metal lines 213, 223, 233 on the dielectric layers on the transistor (TR) region; one of the dielectric layers (210) remaining on the photo diode (PD) region; and a color filter 150 on the dielectric layer 210 in the photo diode (PD) region.

The dielectric layer in the photo diode (PD) region (as well as in the transistor region) may be a premetal dielectric (PMD).

The dielectric layers may include a first dielectric layer 210, a second dielectric layer 220, a third dielectric layer 230, and an uppermost dielectric layer 240.

The metal line may include a first metal (or metallization layer) 213, a second metal (or metallization layer) 223, and a third metal (or metallization layer) 233, and a first plug or via 211, a second plug or via 221, and a third plug or via 231.

The embodiment(s) may further include a microlens 130 on the color filter 150.

In the image sensor according to certain embodiments, the dielectric layers on the photo diode (PD) region are removed by etching (such as reactive ion etching, or RIE) to minimize a path through which light arrives at the PD region, so that the amount of light L1 directly arriving at the PD region can be increased and the transistor (Tr) and/or signal processing characteristic(s) of the image sensor can be improved.

Also, according to certain embodiments, the dielectric layers may have a sloping interface such that a light L2 reflected by the sloping interface can be focused on the PD region. For example, the dielectric layers on the TR region may have a sidewall slope in which a lower portion of each of the dielectric layers has a wider area than an upper portion of each of the dielectric layers, thereby reflecting the light incident thereon toward the PD region to focus the reflected light on a photodiode.

In addition, according to certain embodiments, in order to increase the amount of light incident on the PD region, the metal lines may be spaced apart by a predetermined distance from the PD region.

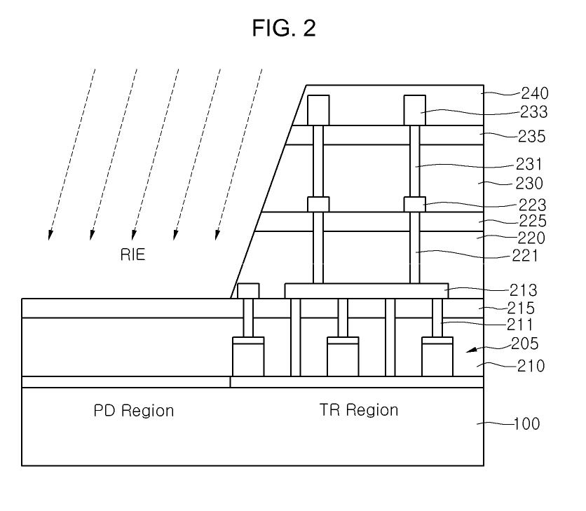

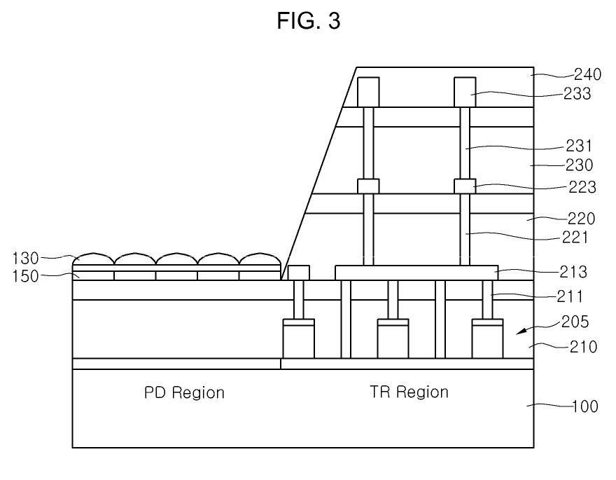

Hereinafter, a method for manufacturing an image sensor according to various embodiments will be described with reference to FIGS. 2 and 3.

First, as shown in FIG. 2, a transistor (TR) region is formed on a substrate 100. For example, one or more transistors 205 may be formed by forming a gate insulating layer and a gate electrode layer on the substrate 100, then patterning the gate insulating and gate electrode layers. The gate insulating layer may comprise silicon dioxide and be formed by wet or dry thermal oxidation of the underlying silicon substrate 100. The gate electrode layer may comprise polysilicon and be formed by chemical vapor deposition (CVD) of silicon (e.g., from silane in the presence of a plasma), optionally followed by an annealing step (e.g., to crystallize the silicon) and/or doping (e.g., by ion implantation). Patterning may comprise conventional photo-lithographic patterning of a photoresist (to be used as a mask) on the polysilicon gate electrode layer, followed by selective etching of the exposed gate electrode and gate insulating layers.

Thereafter, a photo diode (PD) region is formed at one side of the TR region. For example, a photo diode may be formed by forming a relatively deep N-type ion implantation layer (not shown) and a relatively shallow P-type ion implantation layer (not shown) in the exposed PD region of the substrate 100.

Thereafter, a dielectric layer is formed on the PD region and the TR region. The dielectric layer may include a first dielectric layer 210, a second dielectric layer 220, a third dielectric layer 230 and an uppermost dielectric layer 240. Following formation of each of the first dielectric layer 210, second dielectric layer 220, and third dielectric layer 230, a via or plug may be formed therein in accordance with a via/plug pattern, and a metallization layer can be formed thereon in accordance with a metallization pattern.

The first dielectric layer 210 may comprise a lowermost, conformal etch stop layer (e.g., silicon nitride), a conformal buffer and/or gap-fill layer (e.g., silicon-rich oxide [SRO], TEOS [e.g., a silicon oxide formed by CVD from tetraethyl orthosilicate and oxygen], an undoped silicate glass [USG] or a combination thereof), and a bulk dielectric layer (e.g., one or more silicon oxide layers doped with boron and/or phosphorous [BSG, PSG and/or BPSG]). The second dielectric layer 220 and third dielectric layer 230 may comprise the same layers and materials as the first dielectric layer 210, except that the bulk dielectric layer may comprise a low-k dielectric, such as a fluorosilicate glass (FSG), silicon oxycarbide (SiOC) or hydrogenated silicon oxycarbide (SiOCH), any of which may comprise upper and lower low-k dielectric layers above and below an intermediate etch stop layer (e.g., silicon nitride). The uppermost dielectric layer 240 may comprise a conventional passivation layer (e.g., silicon dioxide, silicon nitride, silicon oxynitride, or a combination thereof, such as silicon nitride on silicon dioxide). Each of the capping layers 215, 225 and 235 may comprise, e.g., TEOS, USG, a plasma silane [e.g., silicon dioxide formed by plasma-assisted CVD of silicon dioxide from silane and oxygen], or a combination thereof, such as a bilayer of plasma silane on USG or TEOS, or a bilayer of USG on TEOS.

Next, a metal line process (e.g., a process for forming a plurality of metal lines in a metallization layer) is performed on the dielectric layers on the TR region. The metal line process may include forming a first metal layer 213, a second metal layer 223, and a third metal layer 233. The first metal line layer may be electrically connected to transistor terminals in the TR region by a first plug layer 211, and each successive pair of adjacent metal line layers may be connected to each other by a second plug layer 221 and a third plug layer 231.

For example, a BPSG (borophosphosilicate glass) may be used as a bulk dielectric for the first dielectric layer 210 on the substrate 100 on which the photo diode and the transistor(s) 205 are formed, but the embodiment is not limited thereto. The first dielectric layer 210 may be a PMD. Thereafter, a first capping layer 215 may be formed on the first dielectric layer 210 using plasma assisted decomposition (e.g., plasma-assisted CVD) of silane (plasma-SiH₄) in the presence of an oxygen source (e.g., dioxygen or ozone), but the embodiment is not limited thereto.

Next, the first dielectric layer 210 and the first capping layer 215 may be patterned and etched to form via holes, and then the via holes may be filled with tungsten (e.g., following deposition of adhesion and/or barrier layers, such as a TiN-on-Ti bilayer) to form the first plug 211. Thereafter, the first metal layer 213 may be formed on the first plug 211. The first metal layer 213 may comprise aluminum or an aluminum alloy (e.g., Al with up to 4 wt. % Cu, up to 2 wt. % Ti, and/or up to 1 wt. % Si), on conventional adhesion and/or barrier layers (e.g., Ti and/or TiN, such as a TiN-on-Ti bilayer), and/or covered by conventional adhesion, barrier, hillock suppression, and/or antireflective layers (e.g., Ti, TiN, WN, TiW alloy, or a combination thereof, such as a TiN-on-Ti bilayer or a TiW-on-Ti bilayer).

Next, the second dielectric layer 220 may be formed from CVD TEOS (tetraethyl orthosilicate) on the first metal layer 213, but the embodiment is not limited thereto. Thereafter, a second capping layer 225 may be formed on the second dielectric layer 220 using plasma-SiH₄, but the embodiment is not limited thereto.

Next, the second dielectric layer 220 and the second capping layer 225 may be patterned and etched to form via holes, and then the via holes are filled with tungsten to form the second plug layer 221, generally in a manner similar to or the same as the first plug layer 211. Thereafter, the second metal 223 may be formed on the second plug 221 in a manner similar to or the same as the first metal layer 211.

Next, the third dielectric layer 230 may be formed from CVD TEOS (tetraethyl orthosilicate) on the second metal 223, but the embodiment is not limited thereto. Thereafter, a third capping layer 235 may be formed on the third dielectric layer 230 using plasma-SiH₄, but the embodiment is not limited thereto.

Next, the third dielectric layer 230 and the third capping layer 235 may be patterned and etched to form via holes, and then the via holes are filled with tungsten to form the third plug 231 in a manner similar to or the same as the first and/or second plug layers 211 and/or 221. Thereafter, the third metal layer 233 may be formed on the third plug 231 in a manner similar to or the same as the first and/or second metal layers 213 and/or 223.

Next, the uppermost dielectric layer 240 may comprise USG on the third metal 233, but the embodiment is not limited thereto.

Thereafter, the dielectric layers on the PD region are selectively removed.

For example, the dielectric layers on the PD region may be removed such that only the first dielectric layer 210 remains. The etching may be performed using a reactive ion etching (RIE), but the embodiment is not limited thereto. For example, the dielectric layers on the PD region may be vertically removed such that the first dielectric layer 210 and the first capping layer 215 are left.

In the exemplary method(s) for manufacturing an image sensor, the dielectric layers on the PD region are removed (e.g., by RIE) to minimize a path through which light arrives at the PD region, and/or reduce or minimize a number of light reflections (e.g., at inter-layer interfaces) and/or absorptions (by the dielectric materials themselves), so that the amount of light arriving at the PD region can be increased and the transistor (Tr) and/or processing characteristic(s) of the image sensor can be improved.

Also, according to the exemplary method(s), etching the dielectric layers may be performed under conditions that form a slope on the sidewalls of the second, third and/or fourth dielectric layers 220, 230 and/or 240 (and, optionally, the second and/or third capping layers 224 and/or 235) over the TR region. That is, according to the embodiment, the dielectric layers on the TR region may be etched to have a sloping interface such that light can be focused onto the PD region.

For example, the dielectric layers 220, 230 and 240 over the TR region may be etched to have a slope in which a lower portion of each of the dielectric layers has a wider area than an upper portion of each of the dielectric layers, thereby reflecting the light deviating from the PD region toward the PD region to focus the reflected light on the PD region. Such etching may be comprise dry (plasma) etching or RIE, using an etchant or etchant mixture having a low fluorine-to-carbon (F:C) ratio, relative to CF₄ and/or CHF₃. For example, etchants such as C₂F₆, C₂F₄, C₂H₂F₄, or cyclo-C₄F₈ may be used, alone or in combination with CF₄ and/or CHF₃, and etching additives such as CO (to increase the amount of carbon) and/or Ar (to increase a relative proportion of sputter-etching, which may improve a corner-rounding effect on the uppermost dielectric layer 240) may be added to the etchant. Alternatively, the second, third and/or fourth dielectric layers 220, 230 and/or 240 (and, optionally, the second and/or third capping layers 224 and/or 235) may be directionally etched (e.g., by RIE, as shown in FIG. 2, at an angle of from about 60° to about 88° [or any range of values therein] relative to the substantially horizontal surface of the uppermost dielectric layer 240).

Next, a color filter layer 150 is formed on the dielectric layer remaining on the PD region. The color filter layer 150 may comprise a plurality of color filters (e.g., red, green and blue, or alternatively, yellow, cyan and magenta), each comprising a dye and a resist, patterned in an array over the PD region. Generally, each color filter is formed in a 1:1 correspondence with an underlying photodiode.

Thereafter, in various embodiments, a planarizing layer may be formed on the color filter 150, and a microlens 130 (e.g., a plurality of microlenses in an array) may be further formed on the planarizing layer. Generally, each microlens 130 is formed in a 1:1 correspondence with an underlying photodiode, and generally by patterning a substantially transparent resist in a pre-lens pattern, then reflowing the pre-lens patterned resist to form a microlens having a convex upper surface.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a transistor region on a substrate;
a photo diode region at one side of the transistor region;
a first dielectric layer on the transistor region and the photo diode region;
a metal line on the first dielectric layer in the transistor region; and
a color filter on the first dielectric layer in the photo diode region.

2. The image sensor of claim 1, further comprising a second dielectric layer in the transistor region.

3. The image sensor of claim 2, wherein a lower portion of the second dielectric layer is wider than an upper portion of the second dielectric layer.

4. The image sensor of claim 1, further comprising a microlens over the color filter.

5. The image sensor of claim 1, wherein the first dielectric layer comprises a premetal dielectric (PMD).

6. The image sensor of claim 2, further comprising a first capping layer on the first dielectric layer in the transistor region and in the photo diode region.

7. The image sensor of claim 6, further comprising a second dielectric layer on the first capping layer in the transistor region, and a second capping layer on the second dielectric layer.

8. The image sensor of claim 7, wherein the second dielectric layer has a sloped sidewall at an interface between the transistor region and the photo diode region.

9. A method for manufacturing an image sensor comprising:
forming a plurality of transistors in a transistor region of a substrate;
forming a photo diode in a photo diode region at one side of the transistor region;
forming a first dielectric layer on the photo diode and the plurality of transistors in the photo diode region and the transistor region;
forming a metal line on the dielectric layer in the transistor region;
forming a second dielectric layer on the metal line in the transistor region and on the first dielectric layer in the photo diode region;
selectively removing the second dielectric layer in the photo diode region; and
forming a color filter on the first dielectric layer in the photo diode region.

10. The method of claim 9, wherein selectively removing the second dielectric layer forms a sloped sidewall on the second dielectric layer.

11. The method of claim 10, wherein the sloped sidewall of the second dielectric layer has an angle of from 60° to 88° with respect to a substantially horizontal surface of the first dielectric layer.

12. The method of claim 10, wherein selectively removing the second dielectric layer comprises reactive ion etching with an etchant or etchant mixture having a fluorine-to-carbon (F:C) ratio of less than 4:1.

13. The method of claim 10, wherein selectively removing the second dielectric layer comprises reactive ion etching with an etchant or etchant mixture having a fluorine-to-carbon (F:C) ratio of less than 3:1.

14. The method of claim 9, further comprising a first capping layer on the first dielectric layer in the transistor region and in the photo diode region.

15. The method of claim 14, further comprising a second capping layer on the second dielectric layer.

16. The method of claim 15, wherein the sloped sidewall of the second dielectric layer is at an interface between the transistor region and the photo diode region.

17. The method of claim 16, wherein the second capping layer also has a sloped sidewall at the interface between the transistor region and the photo diode region.

18. The method of claim 9, further comprising, after forming the color filter, forming a microlens on the color filter.

19. The method of claim 9, wherein the first dielectric layer comprises a premetal dielectric (PMD).
